(19) United States
(12) Patent Application Publication
(10) Pub. No.: US 2017/0206950 A1
(43) Pub. Date: Jul. 20, 2017

(54) HIGH RELIABILITY STATIC RANDOM-ACCESS MEMORY CELL

(71) Applicant: Chih-Cheng Hsiao, Taichung City (TW)

(72) Inventor: Chih-Cheng Hsiao, Taichung City (TW)

(21) Appl. No.: 15/475,122

(22) Filed: Mar. 30, 2017

(51) Int. Cl. G11C 11/419

(52) U.S. Cl. CPC G11C 11/419

(57) ABSTRACT

An SRAM cell includes a write inverter including a write pull-up transistor and a write pull-down transistor, a read inverter including a read pull-up transistor and a read pull-down transistor, a write access transistor coupled between an output terminal of the write inverter and a write bit line, and a read access transistor coupled between an output terminal of the read inverter and a read bit line. The SRAM cell performs at least one of a first read operation and a second read operation. Wherein in the first read operation, a voltage of the read bit line is initially at a logic high voltage level, and the write pull-down transistor is not turned on. Wherein in the second read operation, the voltage of the read bit line is initially at a logic low voltage level, and the write pull-up transistor is not turned on.

### BACKGROUND OF THE INVENTION

1. Field of the Invention

The present invention relates to a static random-access memory cell, and more particularly, to a high reliability static random-access memory cell.

2. Description of the Prior Art

Please refer to FIG. 1. FIG. 1 is diagram showing a static random-access memory (SRAM) cell 100 of the prior art. The SRAM cell 100 of the prior art comprises two inverters 110, 120 and two access transistors TA1, TA2. Each of the inverters TA1, TA2 comprises a pull-up transistor TU1, TU2 and a pull-down transistor TD1, TD2 connected in series between a supply voltage source (VDD) and a complementary voltage source (GND). Each of the access transistors TA1, TA2 is connected between a corresponding inverter 110, 120 and a bit line BL1, BL2. The SRAM cell 100 of the prior art performs two-sided write operations and two-sided read operations.

Please refer to FIG. 2. FIG. 2 is diagram showing a static noise margin curve (also called as butterfly curve) of the static random-access memory cell of the prior art. As shown in FIG. 2, voltages VQ1, VQ2 at output terminals Q1, Q2 of the SRAM cell 100 of the prior art are required to be located within static noise margin (SNM) areas M1, M2 for allowing the SRAM cell 100 of the prior art to work normally. If the voltages VQ1, VQ2 at the output terminals Q1, Q2 of the SRAM cell 100 of the prior art are not located within the static noise margin (SNM) areas M1, M2, data stored in the SRAM cell 100 of the prior art is changed.

For, example, in the two-side read operation with the voltage at the output terminal Q1 being at a logic low voltage level (denoted as 0) and the voltage at the output terminal QB being at a logic high voltage level (denoted as 1), the pull-down transistor TD2 is turned on due to the voltage at the output terminal Q1 being pulled up by the voltage of the bit line BL1 to be higher than a threshold voltage of the pull-down transistor TD2, so as to increase possibility of changing data store in the SRAM cell 100. As shown in FIG. 2, when the pull-down transistor TD2 is tuned on and the voltages VQ1, VQ2 at the output terminals Q1, Q2 cross boundaries of the static noise margin (SNM) areas M1, M2, the data stored in the SRAM cell 100 of the prior art is changed.

Moreover, in the two-side write operation with the voltage of the bit line BL1 being at a logic low voltage level (denoted as 0), the voltage of the bit line BL2 being at a logic high voltage level (denoted as 1), the voltage at the output terminal Q1 being at a logic high voltage level (denoted as 1), and the voltage at the output terminal QB being at a logic low voltage level (denoted as 0), the pull-up transistor TU1 is still turned on even though the voltage at the output terminal Q2 of the inverter 120 is pulled up by the voltage of the bit line BL2. In other words, both transistors TU1, TD1 of the inverter 110 are turned on, such that transition of a logic voltage level at the output terminal Q1 of the inverter 110 takes longer time to be completed, and to-be written data may be affected. The prior art uses a negative bit line technique to solve such problem.

Therefore, the SRAM cell 100 of the prior art has lower reliability and smaller noise margin.

### SUMMARY OF THE INVENTION

The present invention provides a SRAM (static random-access memory) cell comprising a write inverter, a read inverter, a write access transistor, and a read access transistor. The write inverter comprises a write pull-up transistor and a write pull-down transistor coupled in series between a supply voltage source and a complementary voltage source. The read inverter comprises a read pull-up transistor and a read pull-down transistor coupled in series between the supply voltage source and the complementary voltage source. An output terminal of the read inverter is coupled to an input terminal of the write inverter. An input terminal of the read inverter is coupled to an output terminal of the write inverter. The write access transistor is coupled between the output terminal of the write inverter and a write bit line. The read access transistor is coupled between the output terminal of the read inverter and a read bit line. Wherein, to-be-written data is written into the SRAM cell via the write access transistor when the write access transistor is turned on, and to-be-read data stored by the SRAM cell is read via the read access transistor when the read access transistor is turned on. Wherein, the SRAM cell performs at least one of a first read operation and a second read operation. Wherein in the first read operation, a voltage of the read bit line is initially at a logic high voltage level when the read access transistor is turned on, and the write pull-down transistor is not turned on. Wherein in the second read operation, the voltage of the read bit line is initially at a logic low voltage level when the read access transistor is turned on, and the write pull-up transistor is not turned on.

The present invention further provides a SRAM (static random-access memory) cell comprising a write inverter, a read inverter, a write access transistor, and a read access transistor. The write inverter comprises a write pull-up transistor and a write pull-down transistor coupled in series between a supply voltage source and a complementary voltage source. The read inverter comprises a read pull-up transistor and a read pull-down transistor coupled in series between the supply voltage source and the complementary voltage source. An output terminal of the read inverter is coupled to an input terminal of the write inverter. An input terminal of the read inverter is coupled to an output terminal of the write inverter. The write access transistor is coupled between the output terminal of the write inverter and a write bit line. The read access transistor is coupled between the output terminal of the read inverter and a read bit line. Wherein, to-be-written data is written into the SRAM cell via the write access transistor when the write access transistor is turned on, and to-be-read data stored by the SRAM cell is read via the read access transistor when the read access transistor is turned on. Wherein, the SRAM cell performs at least one of a first write operation and a second write operation. Wherein in the first write operation, a voltage of the write bit line is at a logic high voltage level, and a voltage at the output terminal of the write inverter turns on the read pull-down transistor and turns off the read pull-up transistor. Wherein in the second write operation, the voltage of the write bit line is at a logic low voltage level, and the voltage at the output terminal of the write inverter turns on the read pull-up transistor and turns off the read pull-down transistor.

The present invention further provides a SRAM (static random-access memory) cell comprising a write inverter, a read inverter, a write access transistor, and a read access transistor. The write inverter comprises a write pull-up transistor and a write pull-down transistor coupled in series between a supply voltage source and a complementary voltage source. The read inverter comprises a read pull-up transistor and a read pull-down transistor coupled in series between the supply voltage source and the complementary voltage source. An output terminal of the read inverter is coupled to an input terminal of the write inverter. An input terminal of the read inverter is coupled to an output terminal of the write inverter. The write access transistor is coupled between the output terminal of the write inverter and a write bit line. The read access transistor is coupled between the output terminal of the read inverter and a read bit line. Wherein, to-be-written data is written into the SRAM cell via the write access transistor when the write access transistor is turned on, and to-be-read data stored by the SRAM cell is read via the read access transistor when the read access transistor is turn on. Wherein, the write access transistor satisfies at least one of a first condition and a second condition. Wherein, the first condition is satisfied when a channel width-to-length ratio of the write access transistor is greater than or equal to 1.25 times a channel width-to-length ratio of the write pull-up transistor, or when an area of the write access transistor is greater than or equal to 1.25 times an area of the write pull-up transistor. Wherein, the second condition is satisfied when the channel width-to-length ratio of the write access transistor is greater than or equal to 2.5 times a channel width-to-length ratio of the write pull-down transistor, or when the area of the write access transistor is greater than or equal to 2.5 times an area of the write pull-down transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is diagram showing a static random-access memory cell (SRAM) of the prior art.

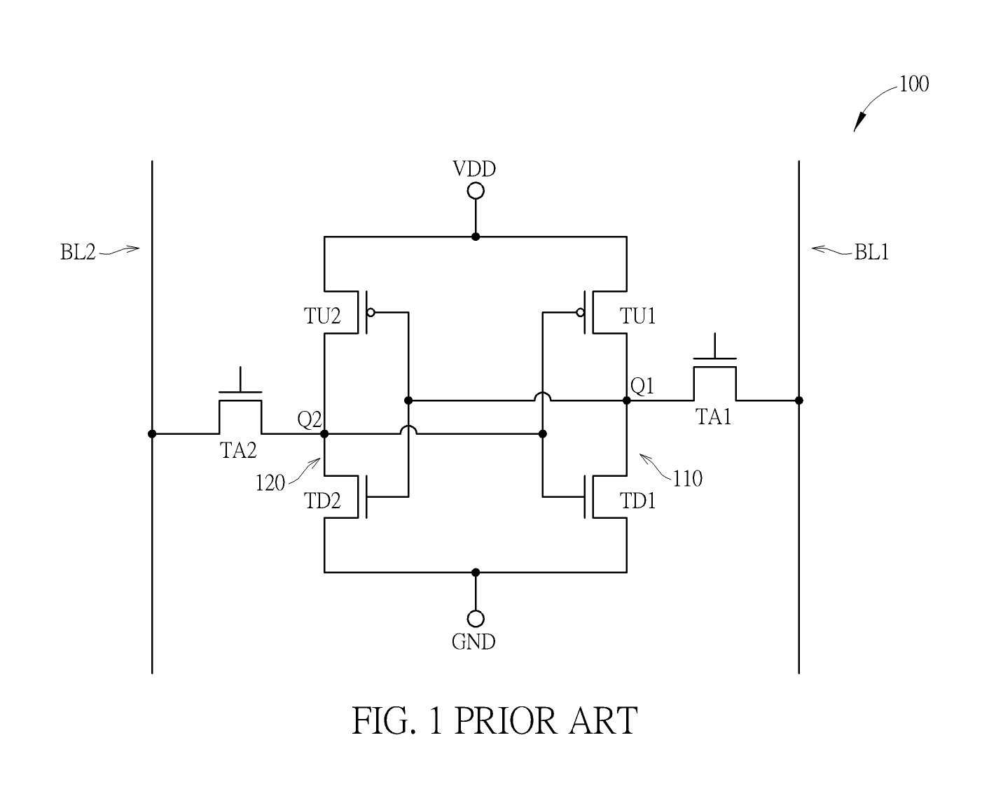

FIG. 2 is diagram showing a static noise margin curve of the static random-access memory cell of the prior art.

FIG. 3 is a diagram showing a SRAM cell according to a first embodiment of the present invention.

FIG. 4 is a diagram illustrating a first read operation of the SRAM cell in FIG. 3.

FIG. 5 is a diagram illustrating a second read operation of the SRAM cell in FIG. 3.

FIG. 6 is a diagram illustrating a first write operation of the SRAM cell in FIG. 3.

FIG. 7 is a diagram illustrating a second write operation of the SRAM cell in FIG. 3.

FIG. 8 is a diagram showing a SRAM cell according to a second embodiment of the present invention.

### DETAILED DESCRIPTION

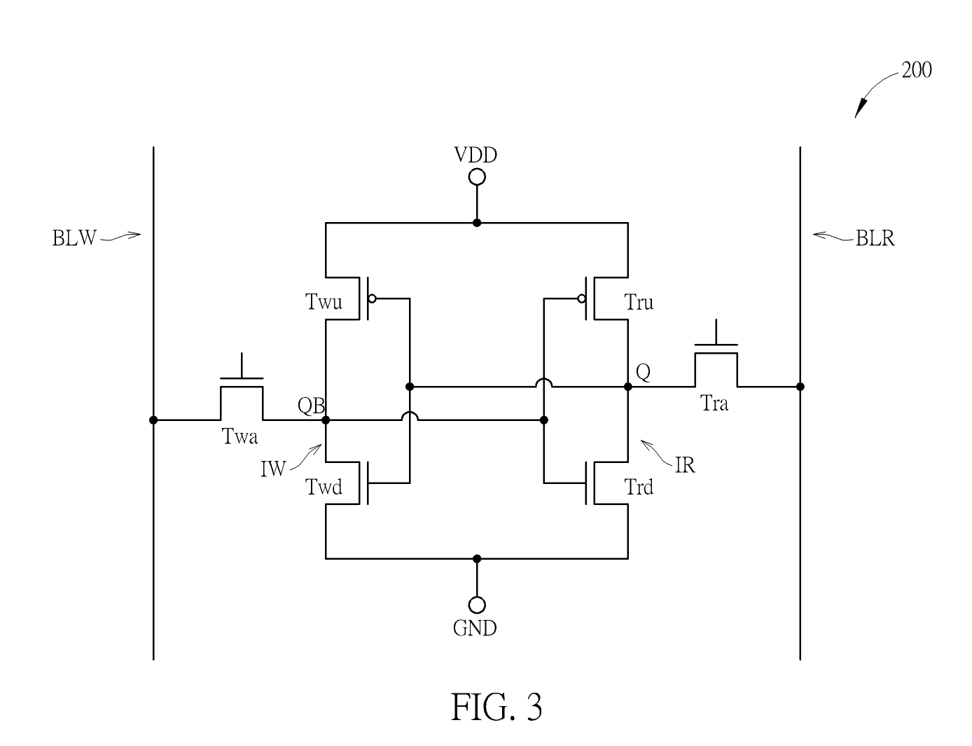

Please refer to FIG. 3. FIG. 3 is a diagram showing a static random-access memory (SRAM) cell of the present invention. As shown in FIG. 3, the SRAM cell 200 of the present invention comprises a write inverter IW, a read inverter IR, a write access transistor Twa, and a read access transistor Tra. The write inverter IW comprises a write pull-up transistor Twu and a write pull-down transistor Twd coupled in series between a supply voltage source VDD and a complementary voltage source GND. The read inverter IR comprises a read pull-up transistor Tru and a read pull-down transistor Trd coupled in series between the supply voltage source VDD and the complementary voltage source GND. An output terminal Q of the read inverter IR is coupled to an input terminal of the write inverter IW. An input terminal of the read inverter IR is coupled to an output terminal QB of the write inverter IW. The write access transistor Twa is coupled between the output terminal QB of the write inverter IW and a write bit line BLW. The read access transistor Tra is coupled between the output terminal Q of the read inverter IR and a read bit line BLR.

Different from the SRAM cell 100 of the prior art, the SRAM cell 200 of the present invention performs one-side write operations and one-side read operations. For example, during a write operation of the SRAM cell 200 of the present invention, the write access transistor Twa is turned on, such that to-be-written data held by the write bit line BLW is written into the SRAM cell 200 via the write access transistor Twa; and during a read operation of the SRAM cell 200 of the present invention, the read access transistor Tra is turned on, such that to-be-read data stored by the SRAM cell 200 is read by the read bit line BLR via the read access transistor Tra. The write access transistor Twa and the read access transistor Tra can be controlled together to be turned on simultaneously, or the write access transistor Twa and the read access transistor Tra can be controlled individually to be turned on at different times.

Moreover, in the present invention, a logic high voltage level (denoted by 1) is a voltage level greater than (VDD-GND)/2, and a logic low voltage level (denoted by 0) is a voltage level smaller than (VDD-GND)/2. In the following embodiments, a voltage level of the supply voltage source VDD is used as the logic high voltage level, and a voltage level of the complementary voltage source GND or a negative voltage level is used as the logic low voltage level, but the present invention is not limited thereto.

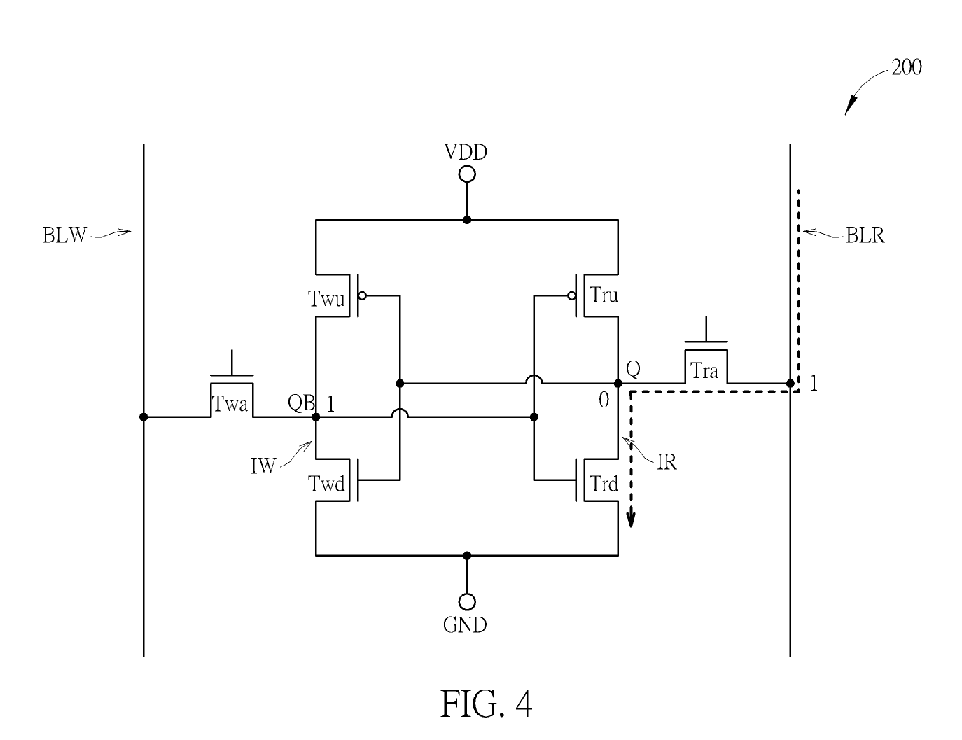

Please refer to FIG. 4. FIG. 4 is a diagram illustrating a first read operation of the SRAM cell of the present invention. As shown in FIG. 4, in the first read operation of the SRAM cell 200 of the present invention, a voltage of the read bit line BLR is initially at a logic high voltage level 1. When a voltage at the output terminal Q of the read inverter IR is at the logic low voltage level 0 and the read access transistor Tra is turned on, the voltage at the output terminal Q of the read inverter IR is pulled up by the voltage of the read bit line BLR. The voltage at the output terminal Q of the read inverter IR after being pulled up can be expressed by the following equation:

VQ1=VDD×RD/(RD+RA)

Wherein, VQ1 represents the voltage at the output terminal Q of the read inverter IR after being pulled up, VDD represents the voltage level of the supply voltage source VDD, RD represents resistance of the read pull-down transistor Trd, and RA represents resistance of the read access transistor Tra. In order to prevent the write pull-down transistor Twd from being turned on, the pulled-up voltage at the output terminal Q of the read inverter IR (which is equal to VDD×RD/(RD+RA)) is required to be smaller than a threshold voltage of the write pull-down transistor Twd, which can be expressed by the following equation:

VQ1<Vtwd

Wherein, Vtwd represents the threshold voltage of the write pull-down transistor Twd. In other words, the SRAM cell 200 of the present invention is designed to have a resistance ratio between the read pull-down transistor Trd and the read access transistor Tra meeting the above requirement. As such, since the write pull-down transistor Twd is not turned on during the first read operation, the data stored in the SRAM cell remains unchanged.

In addition, the smaller the pulled-up voltage VDD×RD/(RD+RA) at the output terminal Q of the read inverter IR is, the greater the noise margin of the SRAM cell 200 in the first read operation is. For example, the noise margin of the SRAM cell 200 in the first read operation can be further increased by the following equation:

VQ1+VX<Vtwd

Wherein, VX represents an additional noise margin of the SRAM cell 200. The present invention can adjust the additional noise margin according to design requirements.

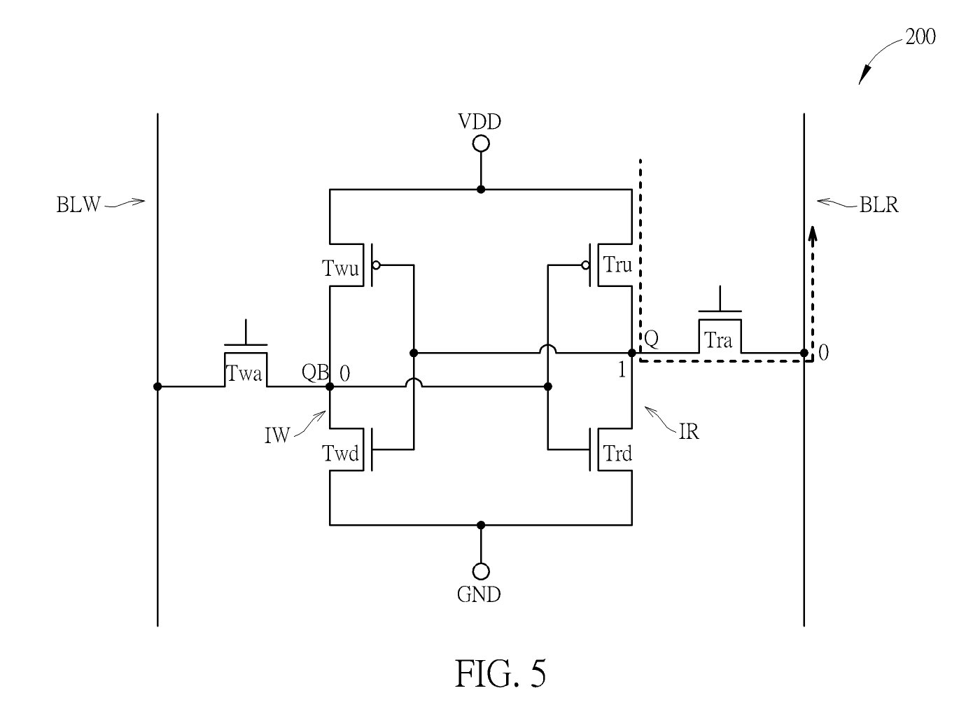

Please refer to FIG. 5. FIG. 5 is a diagram illustrating a second read operation of the SRAM cell of the present invention. As shown in FIG. 5, in the second read operation of the SRAM cell 200 of the present invention, the voltage of the read bit line BLR is initially at a logic low voltage level 0. When the voltage at the output terminal Q of the read inverter IR is at the logic high voltage level 1 and the read access transistor Tra is turned on, the voltage at the output terminal Q of the read inverter IR is pulled down by the voltage of the read bit line BLR. The voltage at the output terminal Q of the read inverter IR after being pulled down can be expressed by the following equation:

VQ2=VDD×RA/(RU+RA)

Wherein, VQ2 represents the voltage at the output terminal Q of the read inverter IR after being pulled down, RU represents resistance of the read pull-up transistor Tru. In order to prevent the write pull-up transistor Twu from being turned on, a result of subtracting the pulled-down voltage at the output terminal Q of the read inverter IR (which is equal to VDD×RA/(RU+RA)) from a voltage of the supply voltage source VDD is required to be smaller than an absolute value of a threshold voltage of the write pull-up transistor Twu, which can be expressed by the following equation:

VDD−VQ2<|Vtwu|

Wherein, |Vtwu| represents the absolute value of the threshold voltage of the write pull-up transistor Twu. In other words, the SRAM cell 200 of the present invention is designed to have a resistance ratio between the read pull-up transistor Tru and the read access transistor Tra meeting the above requirement. As such, since the write pull-up transistor Twu is not turned on during the second read operation, the data stored in the SRAM cell remains unchanged.

In addition, the greater the pulled-down voltage VDD×RA/(RU+RA) at the output terminal Q of the read inverter IR is, the greater the noise margin of the SRAM cell 200 in the second read operation is. For example, the noise margin of the SRAM cell 200 in the first read operation can be further increased by the following equation:

VDD−VQ2+VX<|Vtwu|

In the present invention, the SRAM cell 200 can perform one of the first read operation and the second read operation, or perform both the first read operation and the second read operation.

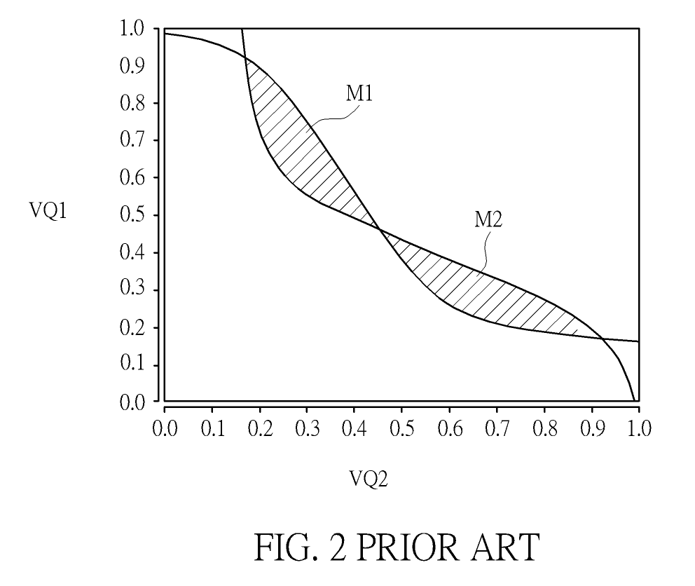

According to the above arrangement, the conduction statuses of the write pull-down transistor Twd and the write pull-up transistor Twu are not changed during the one-side read operation, such that to-be-read data stored in the SRAM cell 200 still remains unchanged. Since the write pull-down transistor Twd is not turned on during the first read operation and the write pull-up transistor Twu is not turned on during the second read operation, the present invention does not need to consider the butterfly curve (as shown in FIG. 2) any more. In the prior art, the resistance of the pull-up transistor is 2 times the resistance of the access transistor. However, in the present invention, the resistance of the read access transistor Tra is greater than or equal to 2 times of the resistance of the read pull-up transistor Tru, and the resistance of the read access transistor Tra is also greater than or equal to 2 times of the resistance of the read pull-down transistor Trd. When the read bit line is short, the voltage of the read bit line can be discharged and charged quickly during the read operation. In such condition, a ratio of the resistance of the read access transistor Tra to the resistance of the read pull-up/pull-down transistor Tru/Trd can be smaller (such as smaller than 2). The point is that the write pull-down transistor Twd is not turned on during the first read operation, and the write pull-up transistor Twu is not turned on during the second read operation.

Therefore, the SRAM cell 200 of the present invention can have better reliability in the one-side read operation.

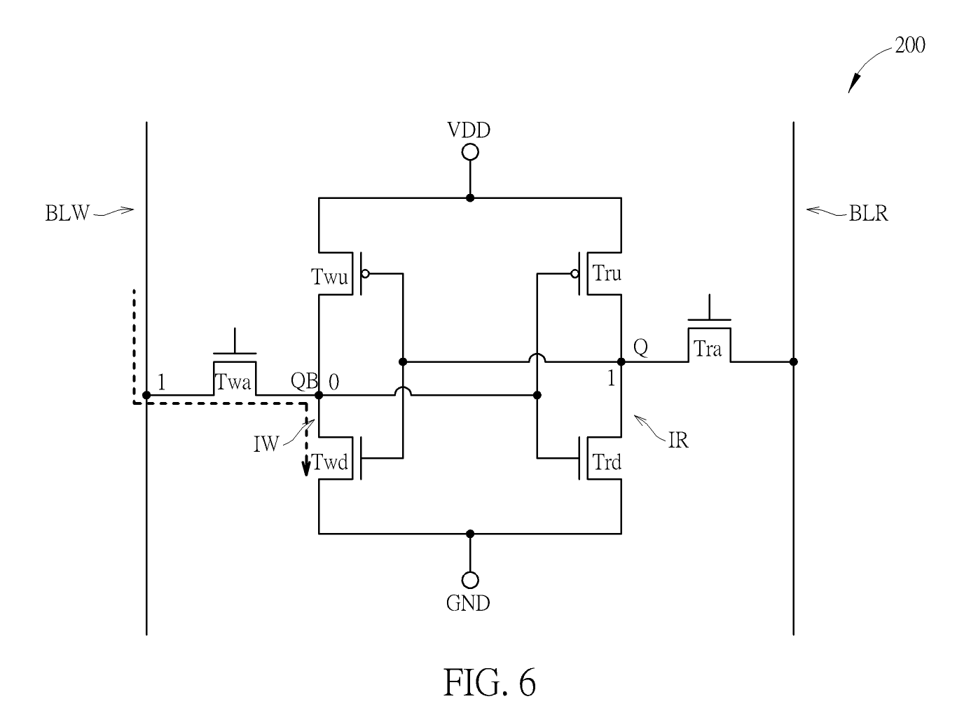

Please refer to FIG. 6. FIG. 6 is a diagram illustrating a first write operation of the SRAM cell of the present invention. As shown in FIG. 6, in the first write operation of the SRAM cell 200 of the present invention, a voltage at the output terminal QB of the write inverter IW is at the logic low level 0 and a voltage of the write bit line is set at the logic high voltage level 1. When the write access transistor Twa is turned on, the voltage at the output terminal QB of the write inverter IW is pulled up by the voltage of the write bit line BLW. The voltage at the output terminal QB of the write inverter IW after being pulled up can be expressed by the following equation:

VQB1=VDD×WD/(WD+WA)

Wherein, VQB1 represents the voltage at the output terminal QB of the write inverter IW after being pulled up, WD represents resistance of the write pull-down transistor Twd, and WA represents resistance of the write access transistor Twa. In order to turn on the read pull-down transistor Trd, the pulled-up voltage at the output terminal QB of the write inverter (which is equal to VDD×WD/(WD+WA)) is required to be greater than a threshold voltage of the read pull-down transistor Trd, which can be expressed by the following equation:

VQB1>Vtrd

Wherein, Vtrd represents the threshold voltage of the read pull-down transistor Twd. Moreover, in order to prevent the read pull-up transistor Tru from being turned on, a result of subtracting the pulled-up voltage at the output terminal QB of the write inverter IW (which is equal to VDD×WD/(WD+WA)) from a voltage of the supply voltage source VDD is required to be smaller than an absolute value of a threshold voltage of the read pull-up transistor Tru, which can be expressed by the following equation:

VDD−VQB1<|Vtru|

Wherein, |Vtru| represents the absolute value of the threshold voltage of the read pull-up transistor Tru. In other words, the SRAM cell 200 of the present invention is designed to have a resistance ratio between the write pull-down transistor Twd and the write access transistor Twa meeting the above requirements. As such, since the read inverter IR has only the read pull-down transistor Trd to be turned on during the first write operation, transition of logic voltage level (from logic high voltage level 1 to logic low voltage level 0) at the output terminal Q of the read inverter IR can be completed faster with higher reliability.

In addition, the greater the pulled-up voltage VDD×WD/(WD+WA) at the output terminal QB of the write inverter IW is, the greater the noise margin of the SRAM cell 200 in the first write operation is. For example, the noise margin of the SRAM cell 200 in the first write operation can be further increased by the following equations:

VQB1−VX>Vtrd

and

VDD−VQB1+VX<|Vtru|

Moreover, in the prior art, the resistance of the pull-down transistor is 0.5 times the resistance of the access transistor. In the present invention, to meet requirements of the first write operation, the resistance of the write pull-down transistor Twd should be greater than or equal to 2.5 times the resistance of the write access transistor Twa. In other words, a channel width-to-length ratio of the write access transistor Twa is greater than or equal to 2.5 times a channel width-to-length ratio of the write pull-down transistor Twd, or an area of the write access transistor Twa is greater than or equal to 2.5 times an area of the write pull-down transistor Twd. To achieve greater noise margin in the first write operation, the resistance of the write pull-down transistor Twd is preferred to be greater than or equal to 3 times the resistance of the write access transistor Twa. In other words, the channel width-to-length ratio of the write access transistor Twa is greater than or equal to 3 times the channel width-to-length ratio of the write pull-down transistor Twd, or the area of the write access transistor Twa is greater than or equal to 3 times the area of the write pull-down transistor Twd.

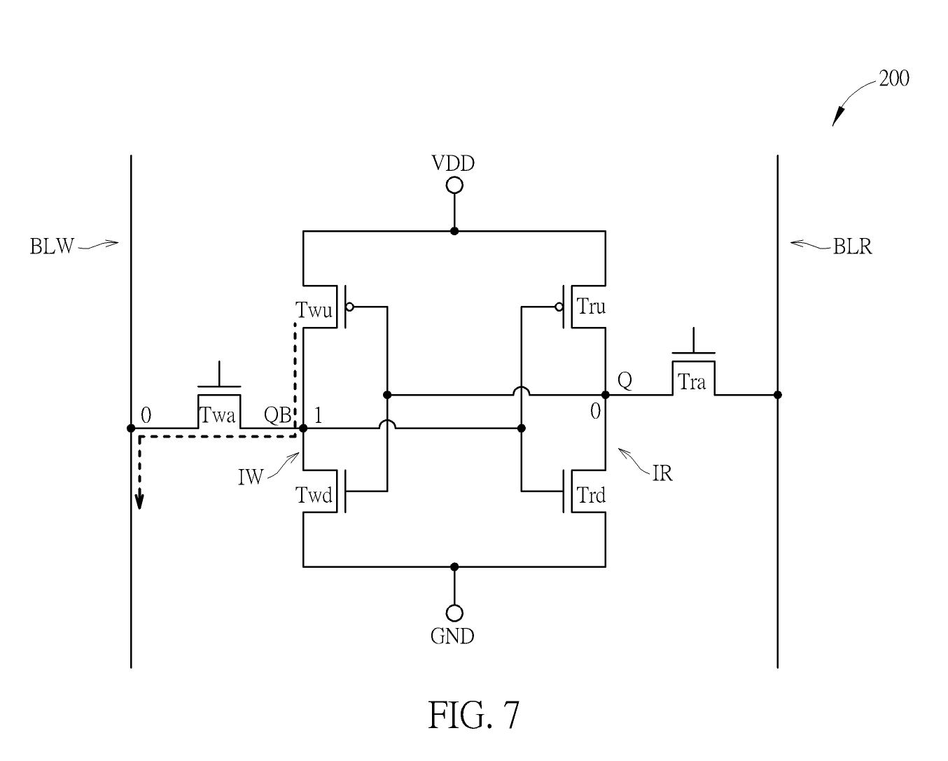

Please refer to FIG. 7. FIG. 7 is a diagram illustrating a second write operation of the SRAM cell of the present invention. As shown in FIG. 7, in the second write operation of the SRAM cell 200 of the present invention, the voltage at the output terminal QB of the write inverter IW is at the logic high level 1 and the voltage of the write bit line BLW is set at a logic low voltage level 0. When the write access transistor Twa is turned on, the voltage at the output terminal QB of the write inverter IW is pulled down by the voltage of the write bit line BLW. The voltage at the output terminal QB of the write inverter IW after being pulled down can be expressed by the following equation:

VQB2=VDD×WA/(WU+WA)

Wherein, VQB2 represents the voltage at the output terminal QB of the write inverter IW after being pulled down, WU represents resistance of the write pull-up transistor Twu. In order to prevent the read pull-down transistor Trd from being turned on, the pulled-down voltage at the output terminal QB of the write inverter IW (which is equal to VDD×WA/(WU+WA)) is required to be smaller than the threshold voltage of the read pull-down transistor Trd, which can be expressed by the following equation:

VQB2<Vtrd

Moreover, in order to turn on the read pull-up transistor Tru, a result of subtracting the pulled-down voltage at the output terminal QB of the write inverter IW (which is equal to VDD×WA/(WU+WA)) from the voltage of the supply voltage source VDD is required to be greater than the absolute value of the threshold voltage of the read pull-up transistor Tru, which can be expressed by the following equation:

VDD−VQB2>|Vtru|

In other words, the SRAM cell 200 of the present invention is designed to have a resistance ratio between the write pull-up transistor Twd and the write access transistor Twa meeting the above requirements. As such, since the read inverter has only the read pull-up transistor Tru to be turned on during the second write operation, transition of logic voltage level (from logic low voltage level 0 to logic high voltage level 1) at the output terminal Q of the read inverter IR can be completed faster with higher reliability.

In addition, the smaller the pulled-down voltage VDD×WA/(WU+WA) at the output terminal QB of the write inverter IW is, the greater the noise margin of the SRAM cell 200 in the second write operation is. For example, the noise margin of the SRAM cell 200 in the second write operation can be further increased by the following equations:

VQB2+VX<Vtrd

and

VDD−VQB2−VX>|Vtru|

Moreover, in the prior art, the resistance of the pull-up transistor is 2 times the resistance of the access transistor, but the resistance ratio between the pull-up transistor and the access transistor cannot allow the read inverter to only turn on one transistor during the write operation. To meet requirements of the second write operation, the resistance WU of the write pull-up transistor Twu should be greater than or equal to 2.5 times the resistance WA of the write access transistor Twa. In other words, the channel width-to-length ratio of the write access transistor Twa is greater than or equal to 1.25 times a channel width-to-length ratio of the write pull-up transistor Twd, or the area of the write access transistor Twa is greater than or equal to 1.25 times an area of the write pull-up transistor Twd (when a PMOS and an NMOS have identical area or channel width-to-length ratio, resistance of the PMOS is 2 times resistance of the NOMS). To achieve greater noise margin in the second write operation, the resistance WU of the write pull-up transistor Twu is preferred to be greater than or equal to 3 times the resistance WA of the write access transistor Twa. In other words, the channel width-to-length ratio of the write access transistor Twa is greater than or equal to 1.5 times the channel width-to-length ratio of the write pull-up transistor Twd, or the area of the write access transistor Twa is greater than or equal to 1.5 times the area of the write pull-up transistor Twd.

In the present invention, the SRAM cell 200 can perform one of the first write operation and the second write operation, or perform both the first read operation and the second read operation.

According to the above arrangement, only one of the read pull-down transistor Trd and the read pull-up transistor Tru is turned on during the one-side write operation, such that transition of logic voltage level at the output terminal Q of the read inverter IR can be completed faster with higher reliability.

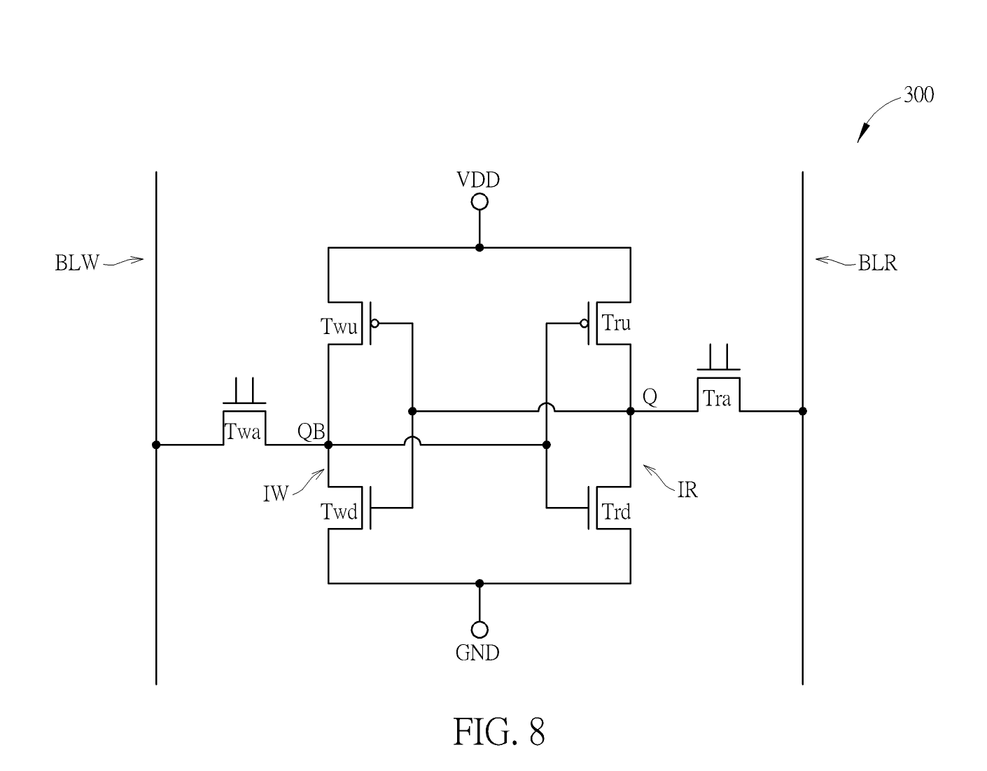

Please refer to FIG. 8. FIG. 8 is a diagram showing a SRAM cell according to a second embodiment of the present invention. As shown in FIG. 8, the write access transistor Twa and the read access transistor Tra of the SRAM cell 300 can be double gate transistors (or multi-gate transistors). In the present embodiment, each of the write access transistor Twa and the read access transistor Tra can be turned on (or conducted) when both two control terminals receive enable signals. In other words, the write access transistor Twa and the read access transistor Tra are independent double gate transistors, but the present invention is not limited thereto. In other embodiment, each of the write access transistor Twa and the read access transistor Tra can be turned on (or conducted) when one control terminal receives the enable signal and the other one control terminal is controlled by a word line or controlled to adjust driving capability of the double gate transistor.

In the present invention, the write access transistor Twa and the read access transistor Tra are not required to be identical type of transistors. For example, the write access transistor Twa can be a single gate transistor and the read access transistor Tra can be a double gate transistor (or a multi-gate transistor), vice versa.

In contrast to the prior art, the conduction statuses of the transistors of the write inverter are not changed during the one-side read operation, such that to-be-read data stored in the SRAM cell remains unchanged. Therefore, the SRAM cell of the present invention can have better reliability in the one-side read operation. Moreover, only one transistor of the read inverter is turned on during the one-side write operation, such that transition of the logic voltage level at the output terminal of the read inverter can be completed faster with higher reliability in the one-side write operation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A SRAM (static random-access memory) cell comprising:
a write inverter comprising a write pull-up transistor and a write pull-down transistor coupled in series between a supply voltage source and a complementary voltage source;
a read inverter comprising a read pull-up transistor and a read pull-down transistor coupled in series between the supply voltage source and the complementary voltage source, an output terminal of the read inverter being coupled to an input terminal of the write inverter, an input terminal of the read inverter being coupled to an output terminal of the write inverter;
a write access transistor coupled between the output terminal of the write inverter and a write bit line; and
a read access transistor coupled between the output terminal of the read inverter and a read bit line;
wherein to-be-written data is written into the SRAM cell via the write access transistor when the write access transistor is turned on, and to-be-read data stored by the SRAM cell is read via the read access transistor when the read access transistor is turned on;
wherein the SRAM cell performs at least one of a first read operation and a second read operation;
wherein in the first read operation, a voltage of the read bit line is initially at a logic high voltage level when the read access transistor is turned on, and the write pull-down transistor is not turned on;
wherein in the second read operation, the voltage of the read bit line is initially at a logic low voltage level when the read access transistor is turned on, and the write pull-up transistor is not turned on.

2. The SRAM cell of claim 1, wherein the SRAM cell performs both the first read operation and the second read operation.

3. The SRAM cell of claim 1, wherein the write access transistor and/or the read access transistor is an independent double gate transistor or a multi-gate transistor.

4. A SRAM (static random-access memory) cell comprising:
a write inverter comprising a write pull-up transistor and a write pull-down transistor coupled in series between a supply voltage source and a complementary voltage source;
a read inverter comprising a read pull-up transistor and a read pull-down transistor coupled in series between the supply voltage source and the complementary voltage source, an output terminal of the read inverter being coupled to an input terminal of the write inverter, an input terminal of the read inverter being coupled to an output terminal of the write inverter;
a write access transistor coupled between the output terminal of the write inverter and a write bit line; and
a read access transistor coupled between the output terminal of the read inverter and a read bit line;
wherein to-be-written data is written into the SRAM cell via the write access transistor when the write access transistor is turned on, and to-be-read data stored by the SRAM cell is read via the read access transistor when the read access transistor is turned on;
wherein the SRAM cell performs at least one of a first write operation and a second write operation;
wherein in the first write operation, a voltage of the write bit line is at a logic high voltage level, and a voltage at the output terminal of the write inverter turns on the read pull-down transistor and turns off the read pull-up transistor;
wherein in the second write operation, the voltage of the write bit line is at a logic low voltage level, and the voltage at the output terminal of the write inverter turns on the read pull-up transistor and turns off the read pull-down transistor.

5. The SRAM cell of claim 4, wherein the SRAM cell performs both the first write operation and the second write operation.

6. The SRAM cell of claim 4, wherein the write access transistor and/or the read access transistor is an independent double gate transistor or a multi-gate transistor.

7. A SRAM (static random-access memory) cell comprising:
a write inverter comprising a write pull-up transistor and a write pull-down transistor coupled in series between a supply voltage source and a complementary voltage source;
a read inverter comprising a read pull-up transistor and a read pull-down transistor coupled in series between the supply voltage source and the complementary voltage source, an output terminal of the read inverter being coupled to an input terminal of the write inverter, an input terminal of the read inverter being coupled to an output terminal of the write inverter;
a write access transistor coupled between the output terminal of the write inverter and a write bit line; and
a read access transistor coupled between the output terminal of the read inverter and a read bit line;
wherein to-be-written data is written into the SRAM cell via the write access transistor when the write access transistor is turned on, and to-be-read data stored by the SRAM cell is read via the read access transistor when the read access transistor is turn on;
wherein the write access transistor satisfies at least one of a first condition and a second condition;
wherein the first condition is satisfied when a channel width-to-length ratio of the write access transistor is greater than or equal to 1.25 times a channel width-to-length ratio of the write pull-up transistor, or when an area of the write access transistor is greater than or equal to 1.25 times an area of the write pull-up transistor;
wherein the second condition is satisfied when the channel width-to-length ratio of the write access transistor is greater than or equal to 2.5 times a channel width-to-length ratio of the write pull-down transistor, or when the area of the write access transistor is greater than or equal to 2.5 times an area of the write pull-down transistor.

8. The SRAM cell of claim 7, wherein the write access transistor satisfies both the first condition and the second condition.

9. The SRAM cell of claim 7, wherein:
wherein the first condition is satisfied when the channel width-to-length ratio of the write access transistor is greater than or equal to 1.5 times the channel width-to-length ratio of the write pull-up transistor, or when the area of the write access transistor is greater than or equal to 1.5 times the area of the write pull-up transistor;
wherein the second condition is satisfied when the channel width-to-length ratio of the write access transistor is greater than or equal to 3 times the channel width-to-length ratio of the write pull-down transistor, or when the area of the write access transistor is greater than or equal to 3 times the area of the write pull-down transistor.

10. The SRAM cell of claim 9, wherein the write access transistor satisfies both the first condition and the second condition.

11. The SRAM cell of claim 7, wherein the write access transistor and/or the read access transistor is an independent double gate transistor or a multi-gate transistor.
